(19) United States
(12) Patent Application Publication
(10) Pub. No.: US 2011/0233772 A1
(43) Pub. Date: Sep. 29, 2011

(54) SEMICONDUCTOR ELEMENT AND SEMICONDUCTOR DEVICE USING THE SAME

(75) Inventors: Hiroaki FUJIMOTO, Osaka (JP); Noriyuki Nagai, Nara (JP); Tadaaki Mimura, Osaka (JP)

(73) Assignee: Panasonic Corporation, Osaka (JP)

(21) Appl. No.: 13/152,095

(22) Filed: Jun. 2, 2011

Related U.S. Application Data
(62) Division of application No. 12/365,542, filed on Feb. 4, 2009.

(30) Foreign Application Priority Data
May 22, 2008 (JP) 2008-134697

(51) Int. Cl. H01L 23/498

(52) U.S. Cl. 257/737; 257/E23.06

(57) ABSTRACT

A semiconductor element includes: a substrate having an integrated circuit; and a wire connection electrode and a bump connection electrode which are provided on a same main surface of the substrate as electrodes having a same connection function to the integrated circuit. The wire connection electrode is provided in a periphery of the main surface. The bump connection electrode is provided inside the wire connection electrode on the main surface. When a straight line dividing the main surface into two regions is determined, the wire connection electrode and the bump connection electrode are located opposite to each other with respect to the straight line.

### CROSS-REFERENCE TO RELATED APPLICATIONS

This application is a Divisional of U.S. application Ser. No. 12/365,542, filed on Feb. 4, 2009, which claims priority under 35 U.S.C. §119(a) on Japanese Patent Application No. 2008-134697 filed on May 22, 2008, the entire contents of each of which are hereby incorporated by reference.

### BACKGROUND OF THE INVENTION

Conventionally, a semiconductor element has electrodes for connecting to connection electrodes on a mounting substrate. These electrodes are provided on one main surface of a substrate having an integrated circuit. Two kinds of semiconductor elements have been known in the art for different kinds of electrodes and different kinds of mounting methods. One is a semiconductor element having wire connection electrodes on a main surface and the other is a semiconductor element having bump connection electrodes on a main surface.

For example, Japanese Patent Laid-Open Publication No. 2004-29464 discloses such a semiconductor element.

### SUMMARY OF THE INVENTION

As described above, there have been two kinds of semiconductor elements: a semiconductor element having a plurality of wire connection electrodes on a main surface of a substrate; and a semiconductor element including a plurality of bump connection electrodes on a main surface of a substrate.

It has been actually very difficult to replace the semiconductor element for wire connection with the semiconductor element for bump connection in order to improve the mounting density on a mounting substrate.

Connection electrodes for mounting the semiconductor element for wire connection and connection electrodes for mounting the semiconductor element for bump connection are arranged in a different manner from each other on the mounting substrate. Therefore, the arrangement of the connection electrodes on the mounting substrate sometimes need to be significantly changed in order to replace the semiconductor element of one mounting method with the semiconductor element of another mounting method.

However, circuit patterns for various circuit parts have already been arranged on the mounting substrate. Accordingly, in order to significantly change the arrangement of the connection electrodes for the semiconductor element, the other circuit patterns and the like need also be significantly changed. Design change of the mounting substrate is often avoided for this reason. In this case, two kinds of semiconductor elements, that is, a semiconductor element having wire connection electrodes and a semiconductor element having bump connection electrodes, are conventionally prepared as semiconductor elements having the same function so that either one of the semiconductor elements can be selected according to the mounting substrate.

It is not always possible to replace the semiconductor element (to replace the semiconductor element for wire connection with the semiconductor element for bump connection) with significant design change of the mounting substrate. Therefore, not all the semiconductor elements for wire connection can be replaced with the semiconductor elements for bump connection, and it is therefore necessary to use the two kinds of semiconductor elements simultaneously.

However, preparing two kinds of semiconductor elements is not desirable in terms of productivity and causes significant increase in cost.

In view of the above problems, a technology of enabling mounting of both wire connection and bump connection without the need to prepare two kinds of semiconductor elements and also suppressing increase in cost in a semiconductor element and a semiconductor device will now be described.

A semiconductor element of this disclosure includes: a substrate having an integrated circuit; and a wire connection electrode and a bump connection electrode which are provided on a same main surface of the substrate as electrodes having a same connection function to the integrated circuit.

In other words, the wire connection electrode and the bump connection electrode provided on the same main surface of the substrate have the same function regarding input and output of signals to and from the integrated circuit provided in the semiconductor element. The semiconductor element of this disclosure can therefore be mounted both by wire connection by using the wire connection electrode and by bump connection by using the bump connection electrode.

As a result, even when both wire connection and bump connection are required as a mounting method of the semiconductor element, it is not necessary to prepare two kinds of semiconductor elements for wire connection and bump connection. Reduction in cost can thus be implemented.

Note that the wire connection electrode is provided in a periphery of the main surface, and the bump connection electrode is provided inside the wire connection electrode on the main surface. This structure enables both wire connection and bump connection to be performed easily.

The semiconductor element is reversed when the mounting method is changed from one method to another between wire connection and bump connection. Accordingly, in order to reverse and mount the semiconductor element, a significant positional change may be required for connection terminals provided on the mounting substrate for electrical connection with the semiconductor element.

This problem can be avoided by appropriately selecting the positions on the main surface of the substrate as a pair of a wire connection electrode and a bump connection electrode having the same connection function to the integrated circuit. The selection method will now be described.

First, when a straight line dividing the main surface into two regions is determined, it is preferable that the wire connection electrode and the bump connection electrode are located opposite to each other with respect to the straight line.

When the straight line dividing the main surface having the bump connection electrode and the wire connection electrode into two regions is considered, the semiconductor element can be reversed with respect to the straight line. The bump connection electrode and the wire connection electrode located opposite to each other with respect to the straight line are thus used as a pair so that the two electrodes have the same connection function to the integrated circuit.

In this case, regarding the wire connection electrode and the bump connection electrode of the pair, the reversed position of the bump connection electrode can be prevented from being located at a totally different position from the original position of the wire connection electrode when the semiconductor element is reversed. This change in position is smaller than that in the case where the bump connection electrode and the wire connection electrode which are located on the same side of the straight line are used as a pair. The same applies to the relation between the original position of the bump connection electrode and the reversed position of the wire connection electrode.

Accordingly, even when the mounting method is changed, no significant positional change is required for the connection terminals on the mounting substrate. The mounting method of the semiconductor element can therefore be easily changed.

When four regions dividing the main surface of the substrate into a two-by-two array are determined, it is preferable that the wire connection electrode is located in one of the four regions and the bump connection electrode is located in another region located adjacent to the one region.

When the four regions dividing the main surface of the substrate into a two-by-two array are considered, the semiconductor element can be reversed on the mounting substrate, for example, so that the region adjacent to the one region is located in the position of the one region. In this case, the wire connection electrode of each region is paired with the bump connection electrode of an adjacent region so that the wire connection electrode and the bump connection electrode of the pair have the same connection function to the integrated circuit.

This structure can also implement a semiconductor element capable of changing the mounting method without significantly moving the connection terminals on the mounting substrate.

When four regions dividing the main surface of the substrate into a two-by-two array are determined, it is also preferable that the wire connection electrode is located in one of the four regions and the bump connection electrode is located in a region that is located in the one region when the substrate is reversed.

This structure can also implement a semiconductor element capable of changing the mounting method without significantly moving the connection terminals on the mounting substrate.

When four regions dividing the main surface of the substrate into a two-by-two array are determined and are clockwise referred to as a first region, a second region, a third region, and a fourth region, it is preferable that a plurality of pairs of the wire connection electrode and the bump connection electrode are provided and the following pairs are provided as the plurality of pairs: a pair of the wire connection electrode located in the first region and the bump connection electrode located in the second region, a pair of the bump connection electrode located in the first region and the wire connection electrode located in the second region, a pair of the wire connection electrode located in the third region and the bump connection electrode located in the fourth region, and a pair of the bump connection electrode located in the third region and the wire connection electrode located in the fourth region.

It is now considered that this semiconductor element is reversed by 180° with respect to a boundary between the first region and the second region. When the semiconductor element is thus reversed, the bump connection electrode of the second region is located near the original position of the wire connection electrode of the first region. Accordingly, by using the wire connection electrode of the first region and the bump connection electrode of the second region as a pair, it is not necessary to significantly move the connection terminal on the mounting substrate which is connected to one electrode of the electrode pair. The same applies to other pairs. This structure can therefore implement a semiconductor element capable of changing the mounting method without significantly moving the connection terminals on the mounting substrate.

Note that, preferably, the substrate is rectangular and includes a dummy electrode in at least one of its corners.

The dummy electrode is effective to improve the heat dissipation property of the semiconductor element. A higher heat dissipation effect can be obtained especially by connecting the dummy electrode to the connection terminal on the mounting substrate when the semiconductor element is mounted by bump connection.

Preferably, the dummy electrode is larger than the bump connection electrode. This further improves the heat dissipation property of the dummy electrode.

Preferably, the dummy electrode is provided in each of a plurality of corners of the substrate, and at least one of the dummy electrodes has a recognition mark.

This facilitates recognition of the direction and the like when operation of mounting the semiconductor element and the like is performed.

A semiconductor device of this disclosure includes: the semiconductor element of this disclosure; and a mounting substrate for mounting the semiconductor element thereon. The semiconductor element is mounted so that the main surface faces an opposite side to the mounting substrate, a plurality of connection terminals are provided in a region outside the semiconductor element on the mounting substrate, and the wire connection electrode of the semiconductor element and the connection terminal of the mounting substrate are connected to each other through a wire.

Another semiconductor device includes: the semiconductor element of this disclosure; and a mounting substrate for mounting the semiconductor element thereon. The semiconductor element is mounted so that the main surface faces the mounting substrate, a plurality of connection terminals are provided in a region inside the semiconductor element on the mounting substrate, and the bump connection electrode of the semiconductor element and the connection terminal of the mounting substrate are connected to each other through a bump.

A semiconductor device using the semiconductor element of this disclosure can thus be structured.

Still another semiconductor device includes: the semiconductor element of this disclosure; and a mounting substrate for mounting the semiconductor element thereon. The semiconductor element is mounted so that the main surface faces the mounting substrate, a plurality of connection terminals are provided in a region inside the semiconductor element on the mounting substrate, the bump connection electrode of the semiconductor element and the connection terminal of the mounting substrate are connected to each other through a bump, and a heat-releasing electrode provided on the mounting substrate and the dummy electrode provided on the semiconductor element are connected to each other through a bump.

In this way, a semiconductor device using any of the above semiconductor elements and having a high heat dissipation property can be structured.

The semiconductor element described above can be mounted by both wire connection and bump connection, and the mounting method can be changed with only a slight design change in connection terminals on the mounting substrate. It is therefore not necessary to prepare a plurality of kinds of semiconductor elements, whereby an extremely useful semiconductor element can be obtained while suppressing increase in cost.

### BRIEF DESCRIPTION OF THE DRAWINGS

FIG. 1 is a diagram showing a planar structure of an example semiconductor element;

FIG. 2 is a cross-sectional view of a semiconductor device having the semiconductor element of FIG. 1 mounted on a mounting substrate by wire connection;

FIG. 3 is a cross-sectional view of a semiconductor device having the semiconductor element of FIG. 1 mounted on a mounting board by bump connection;

FIGS. 4A and 4B are diagrams illustrating the degree of design change that is required for connection terminals on a mounting board when the semiconductor element of FIG. 1 is mounted by wire connection and bump connection; and

FIGS. 5A and 5B are diagrams illustrating design change that is required for a mounting substrate when the mounting method of the semiconductor element of FIG. 1 is changed as in FIGS. 4A and 4B.

FIG. 6 illustrates an exemplary embodiment of the substrate 11 and integrated circuit 60, which is disposed in the substrate 11.

### DETAILED DESCRIPTION OF THE PREFERRED EMBODIMENTS

Hereinafter, examples of a semiconductor element and a semiconductor device will be described with reference to the accompanying drawings.

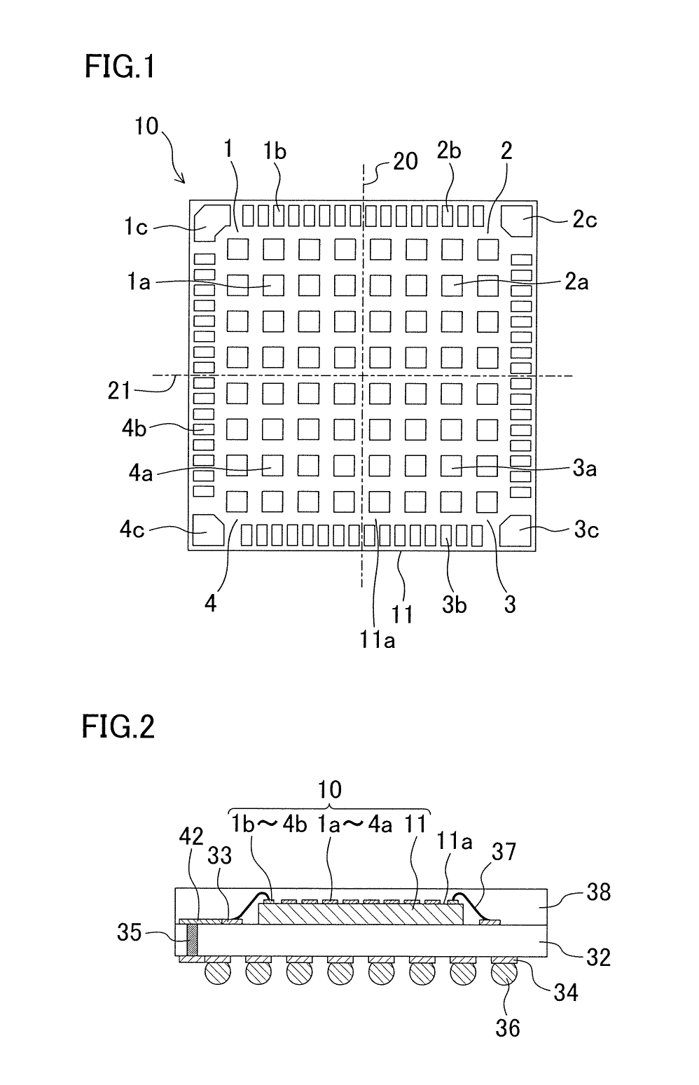

FIG. 1 is a diagram showing a planar structure of an example semiconductor element 10. The semiconductor element 10 is formed by using a square substrate 11 having an integrated circuit (not shown). It is herein assumed that one main surface 11a of the substrate 11 is equally divided into four regions in a two-by-two array by straight lines (20 and 21) connecting the middle points of opposing sides. These four regions are clockwise referred to as a first region 1, a second region 2, a third region 3, and a fourth region 4. In FIG. 1, the upper left region is referred to as the first region 1.

In the first region 1, a plurality of bump connection electrodes 1a are dispersedly arranged in an inner region of the main surface 11a of the substrate 11. A plurality of wire connection electrodes 1b are arranged in the periphery of the main surface 11a of the first region 1.

A plurality of bump connection electrodes 2a, 3a, 4a and a plurality of wire connection electrodes 2b, 3b, 4b are arranged in each of the other three regions 2, 3, and 4. In other words, the wire connection electrodes 1b, 2b, 3b, and 4b are arranged in the periphery of one main surface 11a of the substrate 11, and the bump connection electrodes 1a, 2a, 3a, and 4a are arranged in the region inside the periphery of the main surface 11a.

Note that, in the following description, the bump connection electrodes 1a in the first region 1 are sometimes referred to as first bump connection electrodes 1a. Similarly, the wire connection electrodes 2b in the second region 2 are sometimes referred to as second wire connection electrodes 2b. In this way, an element in each region is sometimes referred to with an ordinal number of that region.

The bump connection electrodes 1a, 2a, 3a, and 4a and the wire connection electrodes 1b, 2b, 3b, and 4b are provided in pairs. The bump connection electrode and the wire connection electrode of each pair perform the same function regarding input and output of signals to and from the integrated circuit of the substrate 11. In other words, when the semiconductor element 10 is mounted on a mounting substrate, it is only necessary that at least one of the bump connection electrode and the wire connection electrode of each pair be electrically connected to the mounting substrate.

Which wire connection electrode forms a pair with which bump connection electrode will be described later.

A dummy electrode is provided in the corners of the substrate 11. In this example, dummy electrodes 1c through 4c are respectively provided in the first through fourth regions 1 through 4. The dummy electrode 1c in the first region 1 has a different planar shape from that of the dummy electrodes 2c through 4c in the other regions so that the different planar shape functions as a recognition mark. It should be noted that all the first to fourth dummy electrodes 1c through 4c may have separate recognition means.

As has been described above, the semiconductor element 10 includes both the bump connection electrodes 1a through 4a and the wire connection electrodes 1b through 4b. The bump connection electrodes and the wire connection electrodes are provided in pairs, and the bump connection electrode and the wire connection electrode of each pair have the same connection function to the integrated circuit of the substrate 11. Accordingly, the semiconductor element 10 can be mounted either by wire connection or bump connection.

As a result, even when the semiconductor element needs to be mounted by wire connection in some cases and by bump connection in other cases, it is not necessary to prepare two kinds of semiconductor elements according to the mounting method, thereby enabling reduction in cost. Each mounting method will now be described.

FIG. 2 is a cross-sectional view showing the case where the semiconductor element 10 is mounted by wire connection.

In FIG. 2, the semiconductor element 10 is mounted on a mounting substrate 32 so that the main surface 11a having the wire connection electrodes 1b through 4b formed thereon faces upward. A plurality of connection terminals 33 are provided in the outer periphery of the mounted region of the semiconductor element 10 on the mounting substrate 32. The plurality of connection terminals 33 are respectively connected to the wire connection electrodes 1b through 4b of the semiconductor element 10 through interconnection wires 37. The semiconductor element 10, the wires 37, the connection terminals 33, and the like are sealed by a sealing resin 38.

External connection terminals 34 are provided on the opposite surface of the mounting substrate 32 to the surface having the semiconductor element 10 mounted thereon. External connection bumps 36 are respectively provided on the external connection terminals 34. The connection terminals 33 are respectively electrically connected to the external connection terminals 34 via through electrodes 35 extending through the substrate 11 and wirings 42.

The semiconductor element 10 can thus be mounted by wire connection by using the wire connection electrodes 1b through 4b. The bump connection electrodes 1a through 4a are not used in this case.

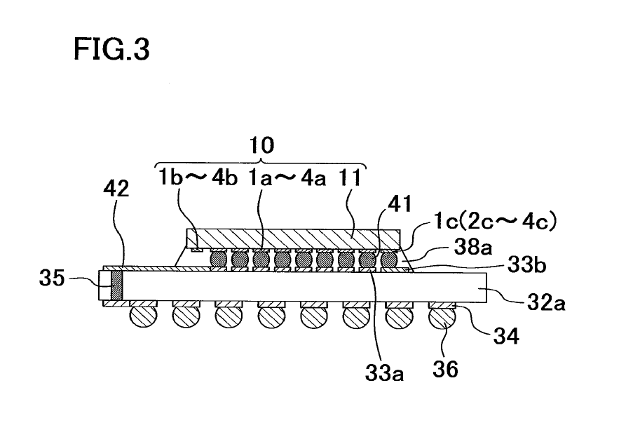

FIG. 3 is a cross-sectional view showing the case where the semiconductor element 10 is mounted by bump connection.

In FIG. 3, the semiconductor element 10 is mounted on a mounting substrate 32a so that the main surface 11a having the bump connection electrodes 1a through 4a formed thereon faces downward. A plurality of connection terminals 33a are provided in a region located under the semiconductor element 10 on the mounting substrate 32a. The plurality of connection terminals 33a are respectively connected to the bump connection electrodes 1a through 4a of the semiconductor element 10 through bumps 41. A sealing resin 38a is formed between the semiconductor element 10 and the mounting substrate 32a.

Note that external connection terminals 34, external connection bumps 36, through electrodes 35, wirings 42, and the like are the same as those of FIG. 2.

The semiconductor element 10 can thus be mounted by bump connection by using the bump connection electrodes 1a through 4a. The wire connection electrodes 1b through 4b are not used in this case.

The mounting substrate (FIG. 2) for wire connection and the mounting substrate (FIG. 3) for bump connection are different only in the connection terminals (33, 33a) provided on the mounting surface of the semiconductor element 10. By appropriately selecting pairs of wire connection electrode and bump connection electrode having the same connection function to the integrated circuit, only a slight change is required for the connection terminals. In other words, the connection terminals need only be moved slightly.

Hereinafter, selection of pairs of wire connection electrode and bump connection electrode will be described.

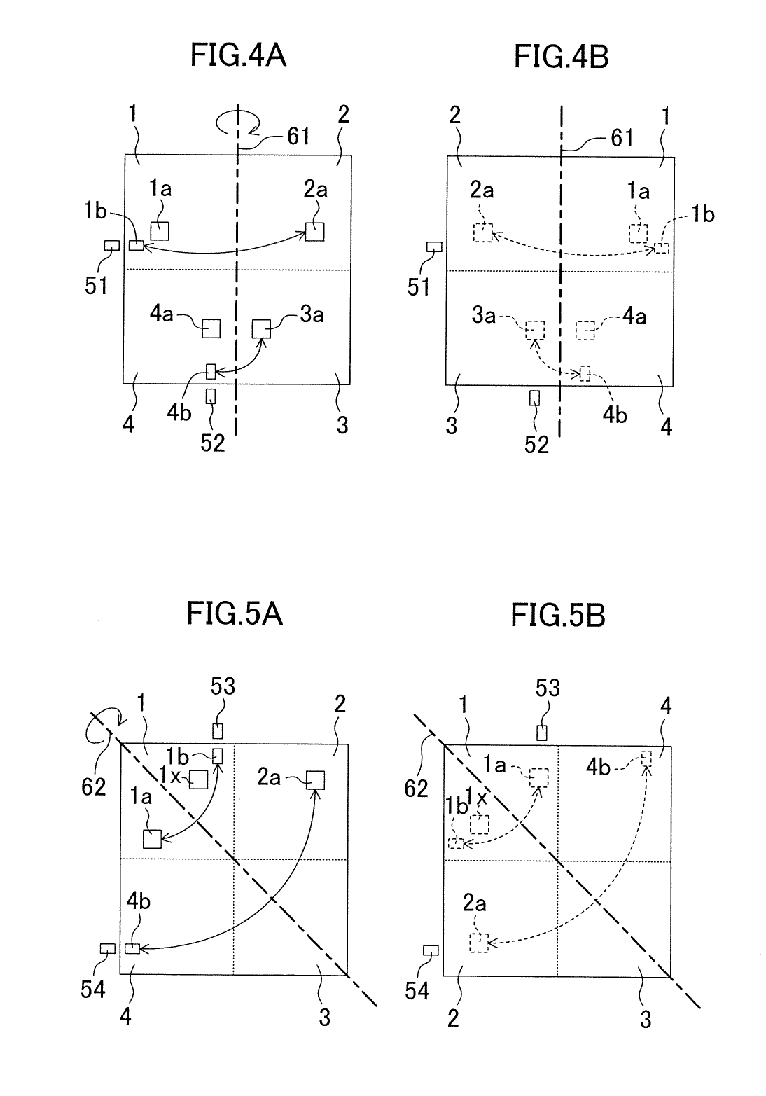

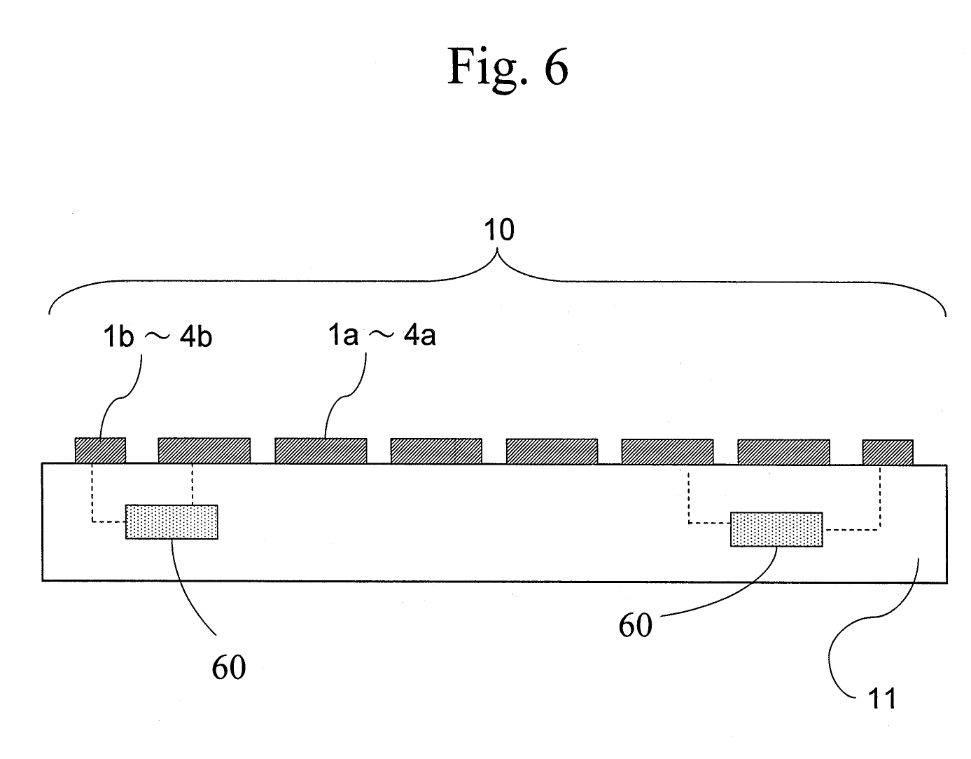

FIG. 4A is a plan view showing the state in which the semiconductor element 10 is mounted by wire connection. It should be noted that only some of the wire connection electrodes 1b through 4b and some of the connection electrodes 1a through 4a are representatively shown in FIG. 4A. No dummy electrodes 1c to 4c are shown in the figure.

When the same semiconductor element 10 is mounted by bump connection, the semiconductor element 10 is reversed. FIG. 4B shows a plan view of the reversed state of the semiconductor element 10. It is herein assumed that the semiconductor element 10 is reversed by 180° with respect to an axis 61 shown in FIG. 4A. The axis 61 extends along a line connecting the middle points of the opposing sides. The axis 61 herein extends along the boundary between the first region 1 and the second region 2.

When the semiconductor element 10 is thus reversed, the positions of the first through fourth regions 1 through 4 are changed. More specifically, the second region 2 is located in the position where the first region 1 was originally located (in the upper left region in FIG. 4A) in the mounting substrate, as shown in FIG. 4B. At the same time, the first region 1 is located in the position of the second region 2, and the fourth region 4 is located in the position of the third region 3, and the third region 3 is located in the position of the fourth region 4.

One first wire connection electrode 1b in the first region 1 will now be considered. The first wire connection electrode 1b is wire-connected to, for example, one connection terminal provided in a terminal position 51 on the mounting substrate.

It is now assumed that the first wire connection electrode 1b forms a pair with a bump connection electrode 1a in the same first region 1. In this case, when the semiconductor element 10 is reversed, the first bump connection electrode 1a is moved to a position totally different from the original position of the first wire connection electrode 1b, as shown in FIG. 4B. This requires a significant design change of the connection terminal from the terminal position 51. Such electrode-pair selection should therefore be avoided.

Instead, in the semiconductor element 10, as shown in FIG. 4A, the first wire connection electrode 1b forms a pair with the bump connection electrode 2a in the second region 2. In this case, even when the semiconductor element 10 is reversed, the second bump connection electrode 2a is located at a position only slightly different from the original position of the first wire connection electrode 1b. This requires only a small design change of the connection terminal.

In this way, a wire connection electrode and a bump connection electrode which are included in the regions which will be located in the same positions of the mounting substrate before and after the semiconductor element 10 is reversed are selected as a pair. This enables the mounting method of the semiconductor element 10 to be changed without involving significant design change of the mounting substrate.

It is also possible to select a pair of a wire connection electrode and a bump connection electrode which are located opposite to each other with respect to the rotation axis 61. Regarding the direction parallel to the axis 61, it is preferable to select a pair of a bump connection electrode and a wire connection electrode which are located as close as possible. Therefore, not the third wire connection electrode 3b in the third region 3 but the second wire connection electrode 2b in the second region 2 is selected to form a pair with the first bump connection electrode 1a in the first region 1.

Note that, in FIGS. 4A and 4B, another example of the electrode pair having the same function to the integrated circuit is shown by a terminal position 52, the fourth wire connection electrode 4b, the fourth bump connection electrode 4a, and the third bump connection electrode 3a.

In other words, the fourth wire connection electrode 4b that is wire-connected to the connection terminal of the terminal position 52 forms a pair with the third bump connection electrode 3a. In this case, when the mounting method is changed, a required design change of the connection terminal is smaller than that in the case where the fourth wire connection electrode 4b forms a pair with the fourth bump connection electrode 4a.

In order to reduce the design change of the mounting substrate required by reversing the semiconductor element 10, a wire connection electrode in one region and a bump connection electrode in a region adjacent to the one region, for example, can be selected as a pair.

Specific examples of the electrode pairs in the semiconductor element 10 of the plan view of FIG. 1 are as follows: the first wire connection electrode 1b and the second bump connection electrode 2a; the first bump connection electrode 1a and the second wire connection electrode 2b; the third wire connection electrode 3b and the fourth bump connection electrode 4a; and the third bump connection electrode 3a and the fourth wire connection electrode 4b. Each pair has the same connection function to the integrated circuit provided on the substrate 11.

Although only one electrode of each electrode type such as the first wire connection electrode 1b has been described above, a plurality of electrodes are provided for each electrode type as shown in FIG. 1. A plurality of pairs can therefore be formed by the same selection method as that described above.

Although not shown in FIG. 3, the dummy electrodes 1c through 4c are respectively connected to heat-releasing electrodes on the mounting substrate 32a through bumps. This can improve the heat dissipation efficiency from the semiconductor element 10 to the mounting substrate 32a. Moreover, as shown in FIG. 1, it is preferable that the dummy electrodes 1c through 4c are provided in the corners of the main surface 11a and the dummy electrodes 1c through 4c are larger than the bump connection electrodes 1a through 4a. This structure enables the semiconductor element 10 to be reliably fixed to the mounting substrate 32a and also enables further improvement in heat dissipation efficiency.

Moreover, the recognition mark of the first dummy substrate 1c can be used to recognize the direction of the semiconductor element 10 (the arrangement direction of each region with respect to the mounting substrate), to perform operation of reversing the semiconductor substrate 10, and the like.

Note that the above description is given to the case where the substrate 11 is square. However, the present invention is not limited to this. For example, the semiconductor element may be formed by using a rectangular substrate 11. In the above description, it is assumed that the main surface 11a is equally divided into the four regions, the first region 1 through the fourth region 4 (in a specific example, the main surface 11a is divided by the two straight lines 20 and 21 connecting the middle points of the opposing sides). Although this is a desirable form, it is not essential to exactly equally divide the main surface into four.

(Modification)

A modification will now be described. In the above example, as shown in FIGS. 4A and 4B, the semiconductor element 10 is reversed with respect to the axis 61 extending along the boundary between the first region 1 and the second region 2. As shown in FIGS. 5A and 5B, however, the semiconductor element 10 having a square substrate 11 may be reversed with respect to an axis 62 extending along the diagonal line of the substrate 11.

In this case, even if the semiconductor element 10 is reversed, the positions of the first region 1 and the third region 3 will not change from their original positions. The positions of the second region 2 and the fourth region 4 will become opposite from the original positions.

In this case as well, a wire connection electrode and a bump connection electrode which are included in the regions which will be located in the same positions of the mounting substrate before and after the semiconductor element 10 is reversed are selected as a pair so that the wire connection electrode and the bump connection electrode of the pair have the same function to the integrated circuit.

Examples of the electrode-pair selection will now be given. The position of the first region 1 will not change even if the semiconductor element 10 is reversed. Therefore, the first wire connection electrode 1b and the first bump connection electrode 1a can be used as a pair. In this case, only a slight design change is required for the connection terminal located at a terminal position 53.

The fourth region 4 is located in the position of the second region 2 when the semiconductor element 10 is reversed. Therefore, the second wire connection electrode 2b and the fourth bump connection electrode 4a are used as a pair. In this case as well, only a slight design change is required for the connection terminal located at a terminal position 54.

It is also preferable to select a pair of a wire connection electrode and a bump connection electrode which are located opposite to each other with respect to the rotation axis 62. For example, in FIGS. 5A and 5B, another first bump connection electrode 1x located on the same side as that of the first wire connection electrode 1b with respect to the axis 62 will be considered. In the case where the first bump connection electrode 1x and the first wire connection electrode 1b are used as a pair, as shown in FIG. 5B, a design change required for the connection terminal located at the terminal position 53 is larger than that in the case where the first bump connection electrode 1a and the first wire connection electrode 1b are used as a pair.

It is therefore preferable to use a pair of a wire connection electrode and a bump connection electrode which are located opposite to each other with respect to the rotation axis of the semiconductor element. Note that, since the diagonal line of the square main surface 11a is herein used as the rotation axis 62, the axis 62 divides the main surface 11a line-symmetrically. Although the use of such an axis is desirable, the present invention is not limited to this.

1-10. (canceled)

11. A semiconductor device, comprising:
a substrate having a first surface with a plurality of connection terminals and a second surface with a plurality of external connection terminals which is opposite to the first surface;
a plurality of external connection bumps provided on the external connection terminals of the substrate; and
a semiconductor element mounted on the first surface of the substrate having an integrated circuit, first electrodes provided in a periphery region of the main surface, and second electrodes located closer to the center of the main surface than the first electrodes,
wherein the first electrodes and the second electrodes are provided in pairs located opposite to each other with respect to a straight line dividing the main surface into two substantially symmetric regions, and each of the pair of the first electrodes and second electrodes connection perform the same connection function to the integrated circuit, and
either the first electrodes or the second electrodes of the semiconductor element connect to the connection terminals of the substrate, and terminals not connecting to the connection terminals sealed by sealing resin.

12. The semiconductor device according to claim 11, wherein said straight line extends parallel to first edge and a second edge which is opposite to the first edge of said substrate.

13. The semiconductor device according to claim 11, wherein one of the first electrodes is located in a first region of four substantially symmetric regions dividing the main surface of the semiconductor element into a two-by-two array, and one of the second electrodes is located in another region.

14. The semiconductor device according to claim 11, wherein one of the first electrodes is located in a first region of four substantially symmetric regions dividing the main surface of the semiconductor element into a two-by-two array, and one of the second electrodes is located in the first region when the semiconductor element is reversed.

15. The semiconductor device according to claim 13, wherein each of said four substantially symmetric regions has a rectangular configuration.

16. The semiconductor device according to claim 14, wherein each of said four substantially symmetric regions has a rectangular configuration.

17. The semiconductor device according to claim 11, wherein the semiconductor element has a rectangular configuration.

18. The semiconductor device according to claim 11, wherein the semiconductor element has dummy electrodes in at least one of its corners.

19. The semiconductor device according to claim 18, wherein the dummy electrode is larger than the second electrode.

20. The semiconductor device according to claim 18, wherein at least one of the dummy electrodes has a recognition mark.

21. The semiconductor device according to claim 11, wherein
the semiconductor element is mounted on the substrate so that a surface which is opposite to the main surface faces the first surface of the substrate,
the connection terminals in a region outside the semiconductor element on the first surface of the substrate and the first electrodes on the main surface of the semiconductor element connect to each other through a wire.

22. The semiconductor device according to claim 11, wherein
the semiconductor element is mounted on the substrate so that the main surface faces the first surface of the substrate,
the connection terminals in a region facing the semiconductor element on the first surface of the substrate and the second electrodes on the main surface of the semiconductor element connect to each other through a bump.

23. The semiconductor device according to claim 21, wherein the sealing resin seals the first surface of the substrate, the main surface of the semiconductor element, and the wirings.

24. The semiconductor device according to claim 22, wherein the sealing resin is disposed between the first surface of the substrate and the main surface of the semiconductor element, and seals the first electrodes of the substrate, the main surface of the semiconductor element.

25. The semiconductor device according to claim 11, wherein one of the first electrodes is located in a first region of four substantially symmetric regions dividing the main surface of the semiconductor element into a two-by-two array, and one of the second electrodes is located in another region located adjacent to the first region.

26. The semiconductor device according to claim 11, wherein each symmetric region has a rectangular configuration.

27. The semiconductor device according to claim 26, wherein each of said two symmetric regions has substantially the same size.
